(19) United States
(12) Patent Application Publication
(10) Pub. No.: US 2025/0204224 A1
(43) Pub. Date: Jun. 19, 2025

(54) DISPLAY PANELS AND DISPLAY DEVICES

(71) Applicant: WUHAN CHINA STAR OPTOELECTRONICS SEMICONDUCTOR DISPLAY TECHNOLOGY CO., LTD., Wuhan, Hubei (CN)

(72) Inventor: Kai HU, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/291,450

(22) PCT Filed: Dec. 18, 2023
(86) PCT No.: PCT/CN2023/139452

§ 371 Date: Jan. 23, 2024

(30) Foreign Application Priority Data
Dec. 13, 2023 (CN) 202311721842

(51) Int. Cl. H10K 59/80; H10K 59/35

(52) U.S. Cl. CPC H10K 59/876; H10K 59/873; H10K 59/35

(57) ABSTRACT

The present disclosure provides a display panel and a display device. A first light emitting layer emits light with a first wavelength λ₁, and a second light emitting layer emits light with a second wavelength λ₂ that is smaller than the first wavelength λ₁. An orthographic projection of a first capping unit on a substrate layer overlaps an orthographic projection of the first light emitting layer on the substrate layer. An orthographic projection of a second capping unit on the substrate layer overlaps an orthographic projection of the second light emitting layer on the substrate layer. A thickness of at least a part of the first capping unit is greater than a thickness of at least a part of the second capping unit.

### TECHNICAL FIELD

The present disclosure relates to display technologies, and in particular, to display panels and display devices.

### BACKGROUND

Organic light emitting diode (OLED) display has many advantages such as wide viewing angle, high contrast and fast response. However, organic light emitting diode display devices have a problem of high power consumption when displaying a highlight picture.

Therefore, it is necessary to propose a technical solution to reduce the power consumption of the organic light emitting diode display device during display.

### SUMMARY

In view of the above, the present disclosure provides a display panel and a display device to reduce the power consumption of the display panel and the display device during display.

In a first aspect, the present disclosure provides a display panel, the display panel includes a substrate layer, a light emitting device layer, a thin film encapsulation layer, and a capping layer. The light emitting device layer is disposed on the substrate layer and includes a transparent anode layer, a light emitting layer and a cathode layer. The light emitting layer is disposed between the transparent anode layer and the cathode layer. The transparent anode layer is located on a side of the light emitting layer close to the substrate layer. The transparent anode layer includes a first transparent anode and a second transparent anode spaced apart. The light emitting layer includes a first light emitting layer disposed on the first transparent anode and a second light emitting layer disposed on the second transparent anode. The first light emitting layer emits light with a first wavelength λ₁, the second light emitting layer emits light with a second wavelength λ₂, and the first wavelength λ₁ is greater than the second wavelength λ₂. The thin film encapsulation layer is located on a side of the light emitting device layer away from the substrate layer. The capping layer is disposed between the cathode layer and the thin film encapsulation layer. A refractive index of the capping layer is greater than a refractive index of the cathode layer. The capping layer includes a first capping unit and a second capping unit. An orthographic projection of the first capping unit on the substrate layer overlaps an orthographic projection of the first light emitting layer on the substrate layer. An orthographic projection of the second capping unit on the substrate layer overlaps an orthographic projection of the second light emitting layer on the substrate layer. A thickness of at least a part of the first capping unit is greater than a thickness of at least a part of the second capping unit.

In a second aspect, the present disclosure further provides a display device, the display device includes the display panel described above.

### Beneficial Effects

In some embodiments of the present disclosure, the refractive index of the capping layer is greater than the refractive index of the cathode layer, which is beneficial to improving the light extraction efficiency of the light emitted by the light emitting layer incident from the cathode layer to the capping layer. Furthermore, the first light emitting layer emits light with the first wavelength λ₁, the second light emitting layer emits light with the second wavelength λ₂, and the first wavelength λ₁ is greater than the second wavelength λ₂. The orthographic projection of the first capping unit on the substrate layer overlaps the orthographic projection of the first light emitting layer on the substrate layer. The orthographic projection of the second capping unit on the substrate layer overlaps the orthographic projection of the second light emitting layer on the substrate layer. The thickness of at least a part of the first capping unit is greater than the thickness of at least a part of the second capping unit. With this arrangement, the first capping unit with a larger thickness is provided for the first wavelength λ₁ which is a larger wavelength. The second capping unit with a smaller thickness is provided for the second wavelength λ₂ which is a smaller wavelength. The thicknesses of the capping layer are designed differentially for light with different wavelengths. The microcavity length of the microcavity structure including the first capping unit matches the first wavelength λ₁, and the microcavity length of the microcavity structure including the second capping unit matches the second wavelength λ₂, which are beneficial to further simultaneously increasing the light extraction efficiencies of the light with the first wavelength and of the light with the second wavelength. The current of the display panel when displaying a bright picture is reduced, thereby reducing the power consumption of the display device when displaying a bright picture, and reducing the heat to address the heating problem.

### BRIEF DESCRIPTION OF THE DRAWINGS

FIG. 1 is a schematic diagram of a cross-sectional structure of a display panel provided by some embodiments of the present disclosure.

FIG. 2 is a partially enlarged schematic diagram of a cross-sectional structure of a display panel provided by some embodiments of the present disclosure.

FIG. 3 is a diagram of a spectrum test result of the transmittance of the first color resist unit, the second color resist unit and the third color resist unit of the filter layer in the display panel for light with different wavelengths provided by some embodiments of the present disclosure.

FIG. 4 is a schematic diagram of a structure of a display device provided by some embodiments of the present disclosure.

Reference numerals are as follows:
100, display panel; 200, display device;
11, substrate layer; 121, driving circuit layer; 122, pixel definition layer; 122a, pixel opening;
13, light emitting device layer; 131, anode layer; 1311, first anode; 1312, second anode; 1313, third anode; 1314, first transparent anode layer; 1315, reflective anode layer; 1316, second transparent anode layer; 1317, first transparent anode; 1318, second transparent anode; 1319, third transparent anode; 132, light emitting layer; 1321, first light emitting layer; 1322, second light emitting layer; 1323, third light emitting layer; 133, cathode layer; 134, hole transport layer; 136, electron transport layer; 137, electron injection layer;
135, dimming layer; 1351, first dimming unit; 1352, second dimming unit; 1353, third dimming unit;
14, capping layer; 141, first capping unit; 1411, first middle portion; 1412, first marginal portion; 142, second capping unit; 1421, second middle portion; 1422, second marginal portion; 143, third capping unit; 1431, third middle portion; 1432, third marginal portion;
15, thin film encapsulation layer; 16, protective layer; 17, touch layer;
18, filter layer; 181, black matrix; 181a, opening; 182, first color resist unit; 183, third color resist unit; 184, second color resist unit;
19, planarization layer; 201, first microcavity structure; 202, second microcavity structure; 203, third microcavity structure.

### DETAILED DESCRIPTION

The technical solutions in the embodiments of the present disclosure will be clearly and completely described below with reference to the accompanying drawings in the embodiments of the present disclosure. It is apparent that the embodiments described are only part of the embodiments of the present disclosure, but not all the embodiments of the present disclosure. Based on the embodiments in the present disclosure, all other embodiments obtained by those skilled in the art without making creative efforts fall within the scope of protection of the present disclosure.

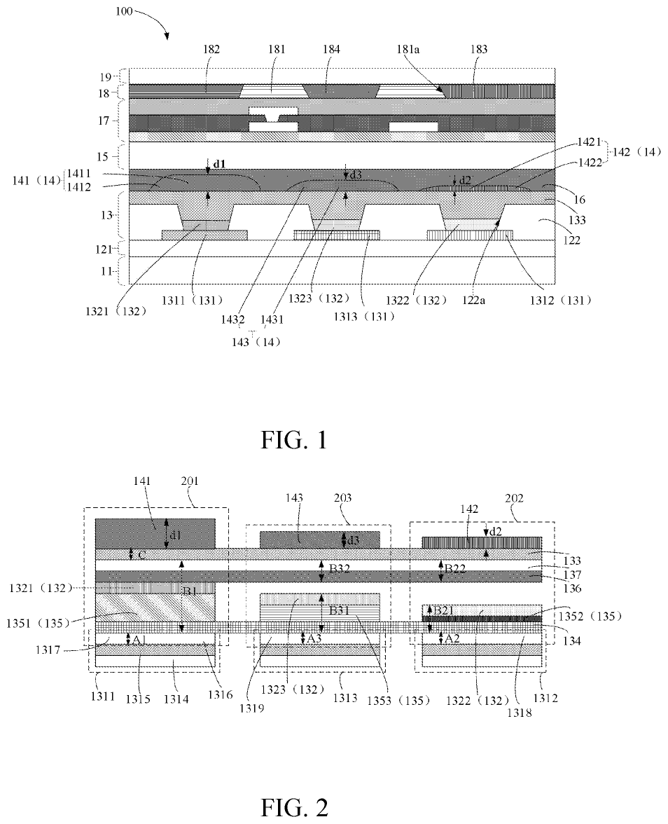

Referring to FIG. 1, it is a schematic diagram of a cross-sectional structure of a display panel in some embodiments of the present disclosure. The display panel 100 includes a substrate layer 11, a light emitting device layer 13, a thin film encapsulation layer 15 and a capping layer 14.

The substrate layer 11 may be a flexible substrate or a rigid substrate such as a glass substrate. In a specific embodiment, the substrate layer 11 is a flexible substrate. In this way, the display panel can be bent.

The light emitting device layer 13 is disposed on the substrate layer 11. The light emitting device layer 13 includes an anode layer 131, a light emitting layer 132 and a cathode layer 133. The light emitting layer 132 is disposed between the anode layer 131 and the cathode layer 133. The anode layer 131 is located on the side of the light emitting layer 132 close to the substrate layer 11.

Referring to FIG. 2, FIG. 2 is a partially enlarged schematic diagram of a cross-sectional structure of a display panel in some embodiments of the present disclosure. As shown in FIG. 1 and FIG. 2, the anode layer 131 includes a first anode 1311, a second anode 1312 and a third anode 1313 that are spaced apart. The anode layer 131 includes a first transparent anode layer 1314, a reflective anode layer 1315 and a second transparent anode layer 1316 stacked in sequence. The second transparent anode layer 1316 is located on the side of the reflective anode layer 1315 away from the substrate layer 11, that is, the second transparent anode layer 1316 is the top transparent anode layer. The second transparent anode layer 1316 includes a first transparent anode 1317, a second transparent anode 1318 and a third transparent anode 1319 that are spaced apart. The first anode 1311 includes the first transparent anode 1317. The second anode 1312 includes the second transparent anode 1318. The third anode 1313 includes the third transparent anode 1319. The reflective anode layer 1315 further includes three reflective anodes corresponding to the first anode 1311, the second anode 1312 and the third anode 1313, respectively. The first transparent anode layer 1314 is the bottom transparent anode layer. The first transparent anode layer 1314 further includes three transparent anodes corresponding to the first anode 1311, the second anode 1312 and the third anode 1313, respectively.

The thicknesses of the first transparent anode layer 1314 and the second transparent anode layer 1316 are greater than or equal to 10 nanometers and less than or equal to 100 nanometers. Optionally, the thicknesses of the first transparent anode layer 1314 and the second transparent anode layer 1316 are greater than or equal to 20 nanometers and less than or equal to 80 nanometers. Optionally, the thicknesses of the first transparent anode layer 1314 and the second transparent anode layer 1316 are greater than or equal to 30 nanometers and less than or equal to 60 nanometers. The materials of the first transparent anode layer 1314 and the second transparent anode layer 1316 include at least one of indium tin oxide and indium zinc oxide. The material of the reflective anode layer 1315 includes, but is not limited to metal, and the metal includes, but is not limited to silver.

As shown in FIG. 1 and FIG. 2, the light emitting layer 132 includes a first light emitting layer 1321, a second light emitting layer 1322, and a third light emitting layer 1323 that are spaced apart. The first light emitting layer 1321 is disposed on the first transparent anode 1317 of the first anode 1311. The second light emitting layer 1322 is disposed on the second transparent anode 1318 of the second anode 1312. The third light emitting layer 1323 is disposed on the third transparent anode 1319 of the third anode 1313. The first light emitting layer 1321 emits light with the first wavelength λ₁. The second light emitting layer 1322 emits light with the second wavelength λ₂. The third light emitting layer 1323 emits light with the third wavelength λ₃.

The light with the first wavelength λ₁, the light with the second wavelength λ₂, and the light with the third wavelength λ₃ are respectively one of red light, green light, and blue light. In this way, the display panel can emit white light. It can be understood that one of the light with the first wavelength λ₁, the light with the second wavelength λ₂ and the light with the third wavelength λ₃ may also be yellow light, or one of the light with the first wavelength λ₁, the light with the second wavelength λ₂ and the light with the third wavelength λ₃ may include both red light and green light at the same time.

In some embodiments, the light with the first wavelength λ₁ may be one of red light and green light, the light with the third wavelength λ₃ may be another one of red light and green light, and the light with the second wavelength λ₂ may be blue light. In other embodiments, the light with the first wavelength λ₁ may be blue light, one of the light with the second wavelength λ₂ and the light with the third wavelength λ₃ may be red light, and another one of the light with the second wavelength λ₂ and the light with the third wavelength λ₃ is green light.

In order to describe the technical solution of the present disclosure, in this disclosure, the first wavelength λ₁ is greater than the second wavelength λ₂ and the third wavelength λ₃ is greater than the second wavelength λ₂. The light with the first wavelength λ₁ is red light, the light with the second wavelength λ₂ is blue light, and the light with the third wavelength λ₃ is green light. It can be understood that the light with the first wavelength λ₁ may be green light, the light with the third wavelength λ₃ may be red light, and the light with the second wavelength λ₂ may be blue light.

The cathode layer 133 may be formed on the entire surface, and the cathode layer 133 covers the first light emitting layer 1321, the second light emitting layer 1322, and the third light emitting layer 1323. The cathode layer 133 may also be a patterned conductive layer. The cathode layer 133 may be light transmissive or semi-transmissive. The thickness of the cathode layer 133 is greater than or equal to 1 nanometer and less than or equal to 100 nanometers. The material of the cathode layer 133 may include at least one of a transparent conductive material and a metal. The refractive index of the cathode layer 133 is greater than or equal to 1.4 and less than or equal to 1.6. For example, the cathode layer 133 includes magnesium-silver alloy.

In some embodiments, the light emitting device layer 13 may further include at least one of a hole transport layer, a hole injection layer, and an electron blocking layer. In some embodiments, the light emitting device layer 13 may further include at least one of an electron transport layer and an electron injection layer.

For example, in a specific embodiment, as shown in FIG. 2, the light emitting device layer 13 may further include a hole transport layer 134, an electron transport layer 136, an electron injection layer 137 and a dimming layer 135, but it is not limited thereto. The hole transport layer 134, the electron transport layer 136, the electron injection layer 137 and the dimming layer 135 can be made of conventional materials in the prior art, which will not be described in detail herein.

The hole transport layer 134, the electron transport layer 136 and the electron injection layer 137 are common film layers. The hole transport layer 134 is located between the second transparent anode layer 1316 and the light emitting layer 132, and is located on the first transparent anode 1317, the second transparent anode 1318 and the third transparent anode 1319. The electron transport layer 136 is located between the light emitting layer 132 and the cathode layer 133, and is located on the first light emitting layer 1321, the second light emitting layer 1322 and the third light emitting layer 1323. The electron injection layer 137 is located between the electron transport layer 136 and the cathode layer 133.

The dimming layer 135 is configured to adjust the color coordinate of the light emitted by the display panel 100. The dimming layer 135 is located between the hole transport layer 134 and the light emitting layer 132. The dimming layer 135 includes a first dimming unit 1351, a second dimming unit 1352, and a third dimming unit 1353 that are spaced apart from each other. The thickness of the dimming layer 135 is greater than or equal to 1 angstrom and less than or equal to 20 angstroms.

The first dimming unit 1351 is located between the first light emitting layer 1321 and the hole transport layer 134, and the orthographic projection of the first dimming unit 1351 on the substrate layer 11 overlaps the orthogonal projection of the first light emitting layer 1321 on the substrate layer 11. The second dimming unit 1352 is located between the second light emitting layer 1322 and the hole transport layer 134. The orthographic projection of the second dimming unit 1352 on the substrate layer 11 overlaps the orthographic projection of the second light emitting layer 1322 on the substrate layer 11. The third dimming unit 1353 is located between the third light emitting layer 1323 and the hole transport layer 134. The orthographic projection of the third dimming unit 1353 on the substrate layer 11 overlaps the orthographic projection of the third light emitting layer 1323 on the substrate layer 11.

In some embodiments, in a case where the first wavelength λ₁ is greater than the third wavelength λ₃ and the third wavelength λ₃ is greater than the second wavelength λ₂, the thickness of the first dimming unit 1351 is greater than the thickness of the third dimming unit 1353, and the thickness of the third dimming unit 1353 is greater than the thickness of the second dimming unit 1352. In this way, while the dimming layer 135 is used to adjust the color coordinates of the light with the first wavelength λ₁, the second wavelength λ₂, and the third wavelength λ₃, the dimming units with different thicknesses are further used to form different cavity lengths, so as to match the light with different wavelengths. Therefore, the transmittance of the light with the first wavelength λ₁, the second wavelength λ₂, and the third wavelength λ₃ emitted from the light emitting device layer 13 is increased.

It should be noted that in the present disclosure, the thickness is the dimension in the direction pointing from the substrate layer to the light emitting device layer.

The thin film encapsulation layer 15 is located on the side of the light emitting device layer 13 away from the substrate layer 11. The thin film encapsulation layer 15 plays a role in isolating water vapor and oxygen, thereby reducing the risk of water vapor and oxygen invading into the light emitting device layer 13. The thin film encapsulation layer 15 includes a first inorganic insulation layer, an organic insulation layer and a second inorganic insulation layer. The organic insulation layer is disposed between the first inorganic insulation layer and the second inorganic insulation layer. The materials of the first inorganic insulation layer and the second inorganic insulation layer include at least one of silicon nitride, silicon oxide, and silicon oxynitride. The material of the organic insulation layer includes at least one of polyacrylate and polysilane.

The capping layer 14 (CPL) is disposed between the cathode layer 133 and the thin film encapsulation layer 15 and is in contact with the cathode layer 133. The refractive index of the capping layer 14 is greater than the refractive index of the cathode layer 133. When the visible light emitted by the light emitting device layer 13 is incident from the cathode layer 133 to the capping layer 14, since the refractive index of the capping layer 14 is greater, the visible light is incident from the optically thinner medium to the optically denser medium. More of the visible light is incident into the capping layer 14, which is beneficial to improving the light extraction efficiency of the light emitted by the light emitting device layer 13. Therefore, the capping layer 14 is configured to improve the light extraction efficiency of the light emitting device layer 13.

In some embodiments, the thickness of capping layer 14 is greater than or equal to 1 nanometer and less than or equal to 100 nanometers. Therefore, the capping layer 14 has a larger thickness, and the adjustable range of the thickness of the capping layer 14 is wider.

In some embodiments, the refractive index of capping layer 14 is greater than or equal to 1.6 and less than or equal to 1.9. Optionally, the refractive index of the capping layer 14 is greater than or equal to 1.65 and less than or equal to 1.85. Optionally, the refractive index of the capping layer 14 is greater than or equal to 1.7 and less than or equal to 1.8.

In some embodiments, the capping layer 14 may include an organic material with high refractive index. The organic material with high refractive index may include hole transport materials and electron transport materials commonly used in organic light emitting diodes. The capping layer 14 may also include an inorganic material. For example, the capping layer 14 may include tris (8-hydroxyquinoline) aluminum (Alq3 for short), or alternatively, the capping layer 14 may also include ZnSe.

The capping layer 14 includes a first capping unit 141, a second capping unit 142 and a third capping unit 143.

In some embodiments, at least two ones of the first capping unit 141, the second capping unit 142 and the third capping unit 143 may be disposed adjacently and spaced apart. With this arrangement, the risk of cross-color is reduced. In a specific embodiment, any two ones of the first capping unit 141, the second capping unit 142 and the third capping unit 143 are spaced apart from each other.

In other embodiments, at least two ones of the first capping unit 141, the second capping unit 142 and the third capping unit 143 may be disposed adjacently and in contact with each other. With this arrangement, the manufacturing difficulty of the capping layer 14 is reduced.

The orthographic projection of the first capping unit 141 on the substrate layer 11 overlaps the orthographic projection of the first light emitting layer 1321 on the substrate layer 11, that is, the first capping unit 141 is disposed corresponding to the first light emitting layer 1321. With this arrangement, the light extraction efficiency of the light with the first wavelength λ₁ is increased. In some embodiments, the orthographic projection of the first light emitting layer 1321 on the substrate layer 11 is within the orthographic projection of the first capping unit 141 on the substrate layer 11. With this arrangement, more of the light emitted by the first light emitting layer 1321 can pass through the first capping unit 141, thereby increasing the light extraction efficiency of the light with the first wavelength λ₁.

The orthographic projection of the second capping unit 142 on the substrate layer 11 overlaps the orthographic projection of the second light emitting layer 1322 on the substrate layer 11, that is, the second capping unit 142 is disposed corresponding to the second light emitting layer 1322. With this arrangement, the light extraction efficiency of the light with the second wavelength λ₂ is increased. In some embodiments, the orthographic projection of the second light emitting layer 1322 on the substrate layer 11 is within the orthographic projection of the second capping unit 142 on the substrate layer 11. With this arrangement, more of the light emitted by the second light emitting layer 1322 can pass through the second capping unit 142, thereby increasing the light extraction efficiency of the light with the second wavelength λ₂.

The orthographic projection of the third capping unit 143 on the substrate layer 11 overlaps the orthographic projection of the third light emitting layer 1323 on the substrate layer 11, that is, the third capping unit 143 is disposed corresponding to the third light emitting layer 1323. With this arrangement, the light extraction efficiency of the light with the third wavelength λ₃ is increased. In some embodiments, the orthographic projection of the third light emitting layer 1323 on the substrate layer 11 is within the orthographic projection of the third capping unit 143 on the substrate layer 11. With this arrangement, more of the light emitted by the third light emitting layer 1323 can pass through the third capping unit 143 to increase the light extraction efficiency of the light with the third wavelength λ₃.

As shown in FIG. 2, since the light emitted by the first light emitting layer 1321 will be emitted to the reflective anode layer 1315, the light with the first wavelength λ1 emitted to the reflective anode layer 1315 will be reflected by the reflective anode layer 1315, and then pass through the first transparent anode 1317, and then exit after passing through other film layers. Therefore, the light emitted by the first light emitting layer 1321 will pass through the first transparent anode 1317, film layers located between the first transparent anode 1317 and the cathode layer 133, the cathode layer 133 and the first capping unit 141. The first transparent anode 1317, the cathode layer 133, the film layers located between the first transparent anode 1317 and the cathode layer 133, and the first capping unit 141 constitute the first microcavity structure 201. The microcavity length of the first microcavity structure 201 is equal to the sum of the thickness A1 of the first transparent anode 1317, the thickness C of the cathode layer 133, the sum B1 of the thicknesses of the film layers located between the first transparent anode 1317 and the cathode layer 133, and the thickness d1 of the first capping unit 141.

Similarly, the light with the second wavelength λ₂ emitted by the second light emitting layer 1322 will pass through the second transparent anode 1318, the cathode layer 133, film layers located between the second transparent anode 1318 and the cathode layer 133, and the second capping unit 142. The second transparent anode 1318, the cathode layer 133, the film layers located between the second transparent anode 1318 and the cathode layer 133, and the second capping unit 142 constitute the second microcavity structure 202. The microcavity length of the second microcavity structure 202 is equal to the sum of the thickness A2 of the second transparent anode 1318, the thickness C of the cathode layer 133, the sum B2 of the thicknesses of the film layers located between the second transparent anode 1318 and the cathode layer 133 (the sum of the thickness B21 and the thickness B22 in FIG. 2), and the thickness d2 of the second capping unit 142.

The light with the third wavelength λ₃ emitted by the third light emitting layer 1323 will pass through the third transparent anode 1319, the cathode layer 133, film layers located between the third transparent anode 1319 and the cathode layer 133, and the third capping unit 143. The third transparent anode 1319, the cathode layer 133, the film layers located between the third transparent anode 1319 and the cathode layer 133, and the third capping unit 143 constitute the third microcavity structure 203. The microcavity length of the third microcavity structure 203 is equal to the sum of the thickness A3 of the third transparent anode 1319, the thickness C of the cathode layer 133, the sum B3 of the thicknesses of the film layers located between the third transparent anode 1319 and the cathode layer 133 (the sum of thickness B31 and thickness B32 in FIG. 2), and the thickness d3 of the third capping unit 143.

In some embodiments, the thickness A1 of the first transparent anode 1317, the thickness A2 of the second transparent anode 1318, and the thickness A3 of the third transparent anode 1319 may be the same. With this arrangement, the first transparent anode 1317, the second transparent anode 1318 and the third transparent anode 1319 can be manufactured in a same process, thereby simplifying the manufacturing process of the second transparent anode layer 1316.

In other embodiments, the thickness A1 of the first transparent anode 1317, the thickness A3 of the third transparent anode 1319, and the thickness A2 of the second transparent anode 1318 can be decremented in sequence, it is conducive that the microcavity length of the first microcavity structure 201, the microcavity length of the third microcavity structure 203 and the microcavity length of the second microcavity structure 202 are decremented in sequence, thereby increasing the light extraction efficiencies of the light with the first wavelength λ₁, the light with the third wavelength λ₃ and the light with the second wavelength λ₂.

In some embodiments, the sum B1 of the thicknesses of the film layers located between the first transparent anode 1317 and the cathode layer 133, the sum B3 of the thicknesses of the film layers located between the third transparent anode 1319 and the cathode layer 133, and the sum B2 of the thicknesses of the film layers located between the second transparent anode 1318 and the cathode layer 133 may be decremented in sequence. With this arrangement, it is conducive that the microcavity length of the first microcavity structure 201, the microcavity length of the third microcavity structure 203, and the microcavity length of the second microcavity structure 202 are decremented in sequence, thereby increasing the light extraction efficiencies of the light with the first wavelength λ₁, the light with the third wavelength λ₃ and the light with the second wavelength λ₂.

It should be noted that the above-mentioned common film layers, such as the above-mentioned hole transport layer 134, the electron transport layer 136 and the electron injection layer 137, each has a substantially uniform thickness. Therefore, whether B1, B2 and B3 are the same mainly depends on the film layers that are not shared, such as the light emitting layer 132 and the dimming layer 135.

In the present disclosure, the thickness of at least a part of the first capping unit 141 is greater than the thickness of at least a part of the second capping unit 142. The thickness of at least a part of the third capping unit 143 is greater than the thickness of at least a part of the second capping unit 142. In this way, the first capping unit 141 having a larger thickness is provided for the light with the first wavelength λ₁ (which is a longer wavelength) emitted by the first light emitting layer 1321. The second capping unit 142 having a smaller thickness is provided for the light with the second wavelength λ₂ (which is a shorter wavelength) emitted by the second light emitting layer 1322. The third capping unit 143 having a larger thickness is provided for the light with the third wavelength λ₃ emitted by the third light emitting layer 1323. Therefore, with respect to the first wavelength λ₁, the third wavelength λ3 and the second wavelength λ₂ which are reduced in sequence, the thickness of the first capping unit 141, the thickness of the third capping unit 143 and the thickness of the second capping unit 142 are reduced in sequence, and it is conducive that the microcavity length of the first microcavity structure 201, the microcavity length of the third microcavity structure 203, and the microcavity length of the second microcavity structure 202 are decremented in sequence, thereby further increasing the light extraction efficiencies of the light with the first wavelength λ₁, the light with the third wavelength λ₃, and the light with the second wavelength λ₂.

It should be noted that in a case where the first wavelength λ₁ is greater than the third wavelength λ₃, the thickness of at least a part of the first capping unit 141 is greater than the thickness of at least a part of the third capping unit 143. In the case where the first wavelength λ₁ is smaller than the third wavelength λ₃, the thickness of at least a part of the first capping unit 141 is smaller than the thickness of at least a part of the third capping unit 143. Therefore, according to the relative relation between the first wavelength λ₁ and the third wavelength λ₃, the thickness of the third capping unit 143 and the thickness of the first capping unit 141 are determined correspondingly.

In a specific embodiment, as shown in FIG. 1, the first capping unit 141 includes a first middle portion 1411 and a first marginal portion 1412, and the first marginal portion 1412 is disposed around the first middle portion 1411. The orthographic projection of the first light emitting layer 1321 on the substrate layer 11 is within the orthographic projection of the first middle portion 1411 on the substrate layer 11. The thickness of the first middle portion 1411 is greater than the thickness of the first marginal portion 1412. The thickness d1 of the first capping unit 141 is the thickness of the first middle portion 1411 and is also the maximum thickness of the first capping unit 141.

The second capping unit 142 includes a second middle portion 1421 and a second marginal portion 1422, and the second marginal portion 1422 is disposed around the second middle portion 1421. The orthographic projection of the second light emitting layer 1322 on the substrate layer 11 is within the orthographic projection of the second middle portion 1421 on the substrate layer 11. The thickness of the second middle portion 1421 is greater than the thickness of the second marginal portion 1422. The thickness of the second middle portion 1421 is smaller than the thickness of the first middle portion 1411. The thickness of the second marginal portion 1422 is smaller than the thickness of the first marginal portion 1412. The thickness d2 of the second capping unit 142 is equal to the thickness of the second middle portion 1421 and is also the maximum thickness of the second capping unit 142.

The third capping unit 143 includes a third middle portion 1431 and a third marginal portion 1432, and the third marginal portion 1432 is disposed around the third middle portion 1431. The orthographic projection of the third light emitting layer 1323 on the substrate layer 11 is within the orthographic projection of the third middle portion 1431 on the substrate layer 11. The thickness of the third middle portion 1431 is greater than the thickness of the third marginal portion 1432. The thickness of the third middle portion 1431 is greater than the thickness of the second middle portion 1421 and is smaller than the thickness of the first middle portion 1411. The thickness of the third marginal portion 1432 is greater than the thickness of the second marginal portion 1422 and is smaller than the thickness of the first marginal portion 1412. The thickness d3 of the third capping unit 143 is equal to the thickness of the third middle portion 1431 and is also the maximum thickness of the third capping unit 143.

Three different fine metal masks (FMM) can be used to manufacture the first capping unit 141, the second capping unit 142 and the third capping unit 143 which have different thicknesses. In the process of forming the first capping unit 141, the second capping unit 142 and the third capping unit 143 using a fine mask as the mask, due to the influence of the shadow effect, the first marginal portion 1412, the second marginal portion 1422 and the third marginal portion 1432 which have smaller thicknesses will be formed respectively, as shown in FIG. 1. In other words, the first marginal portion 1412, the second marginal portion 1422, and the third marginal portion 1432 are formed due to process reasons.

Based on the above, it can be seen that in the present disclosure, the thicknesses of the capping layer 14 are differentially designed for light with different wavelengths, so as to form different microcavity lengths. For example, for light with a larger wavelength, the thickness of the capping layer 14 is larger to form a larger microcavity length. For example, for red light with a longer wavelength, the thickness d1 of the first capping unit 141 is larger. For light with a smaller wavelength, the thickness of the capping layer 14 is smaller to form a smaller microcavity length. For example, for blue light with a smaller wavelength, the thickness d2 of the second capping unit 142 is smaller. A larger microcavity length is matched with a relatively larger wavelength, and a shorter microcavity length is matched with a relatively smaller wavelength, thereby increasing the overall light extraction efficiency of the light emitted by the display panel. The higher the overall light extraction efficiency, the lower the current of the display panel 100 when displaying a bright picture, thereby reducing the power consumption of the display device 200 when displaying a bright picture, and reducing heat to address the heating problem.

Specifically, in a case where both the first wavelength λ₁ and the third wavelength λ₃ are greater than the second wavelength λ₂, the thickness of at least a part of the third capping unit 143 and the thickness of at least a part of the first capping unit 141 are both greater than the thickness of at least a part of the second capping unit 142. For the first wavelength λ₁ and the third wavelength λ₃, the thickness of the capping unit corresponding to a larger wavelength is larger. In this way, the microcavity length of the first microcavity structure 201 including the first capping unit 141 matches the first wavelength λ₁, and the microcavity length of the second microcavity structure 202 including the second capping unit 142 matches the second wavelength λ₂, and the microcavity length of the third microcavity structure 203 including the third capping unit 143 matches the third wavelength λ₃. The light extraction efficiencies of the light with the first wavelength λ₁, the light with the second wavelength λ₂ and the third wavelength λ₃ are all improved. The overall light extraction efficiency of the display panel is increased, and the current of the display panel 100 when displaying a bright picture is reduced, thereby reducing the power consumption of the display device 200 when displaying a bright picture, and reducing heat to address the heating problem.

It should be noted that in related technologies, the thicknesses of the functional film layers between the anode layer and the cathode layer are differentially designed to increase the light extraction efficiency. However, since some functional film layers between the anode layer and the cathode layer have smaller thicknesses and have other inherent functions, for example, the light emitting layer has a smaller thickness and is used to emit light, adjustment of the thicknesses of these functional film layers may significantly affects the efficiency and chromaticity of the light generated by the light emitting device layer, which may adversely affect the display effect.

While in the present disclosure, since the capping layer 14 is located on the light extraction side of the light emitting device layer 13, the function of the capping layer 14 is to improve the light extraction efficiency, and the thickness of the capping layer 14 has a wide value range. In order to improve the light extraction efficiencies of light with different wavelengths, the thicknesses of the capping layer 14 are differentially designed, while improving the overall light extraction efficiency of the display panel to reduce the power consumption, it has less adverse impact on the optical performance of the display panel 100.

In some embodiments, the shape of the first capping unit 141 may be same as or similar to the shape of at least one of the first light emitting layer 1321 and the first dimming unit 1351. In a specific embodiment, the shape of the first capping unit 141, the shape of the first light emitting layer 1321, and the shape of the first dimming unit 1351 are the same or similar. With this arrangement, the first capping unit 141 can be manufactured using the mask for manufacturing the first light emitting layer 1321 and the first dimming unit 1351, which can save the number of masks for manufacturing the display panel and reduce the cost of manufacturing the display panel. The shapes described above refer to planar shapes. For example, the shape of the first capping unit 141 is a shape corresponding to the orthographic projection of the first capping unit 141 on the substrate layer 11. The shapes of the first light emitting layer 1321 and the first dimming unit 1351 also refer to planar shapes.

In some embodiments, the shape of the second capping unit 142 may be same as or similar to the shape of at least one of the second light emitting layer 1322 and the second dimming unit 1352. In a specific embodiment, the shape of the second capping unit 142, the shape of the second light emitting layer 1322, and the shape of the second dimming unit 1352 are the same or similar. With this arrangement, the second capping unit 142 can be manufactured using the mask for manufacturing the second light emitting layer 1322 and the second dimming unit 1352, which can save the number of masks for manufacturing the display panel and reduce the cost of manufacturing the display panel. The shape of the second capping unit 142 is a shape corresponding to the orthographic projection of the second capping unit 142 on the substrate layer 11, and the shapes of the second light emitting layer 1322 and the second dimming unit 1352 also refer to planar shapes.

In some embodiments, the shape of the third capping unit 143 may be same as or similar to the shape of at least one of the third light emitting layer 1323 and the third dimming unit 1353. In a specific embodiment, the shape of the third capping unit 143, the shape of the third light emitting layer 1323, and the shape of the third dimming unit 1353 are the same or similar. With this arrangement, the third capping unit 143 can be manufactured using the mask for manufacturing the third light emitting layer 1323 and the third dimming unit 1353, which can save the number of masks for manufacturing the display panel and reduce the cost of manufacturing the display panel. The shape of the third capping unit 143 is a shape corresponding to the orthographic projection of the third capping unit 143 on the substrate layer 11, and the shapes of the third light emitting layer 1323 and the third dimming unit 1353 also refer to planar shapes.

In the present disclosure, the shapes being the same means the shapes are completely identical. For example, the shape of the first capping unit 141 and the shape of the first light emitting layer 1321 are both quadrilateral. The shapes being similar means that the two shapes tend to be the same. Shapes being similar can be applied to the situation where two identical shapes have slight differences due to process reasons during the manufacturing process. For example, the shape of the first light emitting layer 1321 is a square, and the shape of the first capping unit 141 is a square with rounded corners.

In some embodiments, in a case where the light with the first wavelength λ₁ is red light, the thickness of the first capping unit 141 is greater than or equal to 600 angstroms and less than or equal to 700 angstroms. Optionally, the thickness of the first capping unit 141 is greater than or equal to 620 angstroms and less than or equal to 680 angstroms. Optionally, the thickness of the first capping unit 141 is greater than or equal to 620 angstroms and less than or equal to 650 angstroms. With this arrangement, it is guaranteed that while the thickness of the first capping unit 141 is larger to increase the microcavity length of the first microcavity structure 201, the manufacturing time of the first capping unit 141 is shortened and the transmittance of light with the first wavelength λ₁ passing through the first capping unit 141 is increased.

In some embodiments, in a case where the light with the second wavelength λ₂ is blue light, the thickness of the second capping unit 142 is greater than or equal to 450 angstroms and less than or equal to 530 angstroms. Optionally, the thickness of the second capping unit 142 is greater than or equal to 460 angstroms and less than or equal to 520 angstroms. Optionally, the thickness of the second capping unit 142 is greater than or equal to 480 angstroms and less than or equal to 510 angstroms. With this arrangement, it is guaranteed that while the thickness of the second capping unit 142 is smaller to reduce the microcavity length of the second microcavity structure 202, the problem of increased manufacturing difficulty caused by the thin thickness of the second coverage unit 142 is addressed.

In some embodiments, in a case where the light with the third wavelength λ₃ is green light, the thickness of the third capping unit 143 is greater than or equal to 540 and less than or equal to 600 angstroms. Optionally, the thickness of the third capping unit 143 is greater than or equal to 550 and less than or equal to 590 angstroms. Optionally, the thickness of the third capping unit 143 is greater than or equal to 560 and less than or equal to 585 angstroms. With this arrangement, it is guaranteed that while the thickness of the third capping unit 143 is moderate so that the microcavity length of the third microcavity structure 203 matches the light with the third wavelength λ₃, the manufacturing difficulty of the third capping unit 143 is reduced.

In some embodiments, the difference between the maximum thicknesses of any two of the first capping unit 141, the second capping unit 142 and the third capping unit 143 is greater than or equal to 20 angstroms and less than or equal to 300 angstroms. Optionally, the difference between the maximum thicknesses of any two of the first capping unit 141, the second capping unit 142 and the third capping unit 143 is greater than or equal to 30 angstroms and less than or equal to 200 angstroms. Optionally, the difference between the maximum thicknesses of any two of the first capping unit 141, the second capping unit 142 and the third capping unit 143 is greater than or equal to 40 angstroms and less than or equal to 150 angstroms. If the difference is too small, the difficulties to differentiate the microcavity lengths of the first microcavity structure 201, the second microcavity structure 202, and the third microcavity structure 203 and to control the thicknesses of different capping units are increased. If the difference is too large, the manufacturing time of the capping unit with a larger thickness will be prolonged, and the manufacturing of the capping unit with a smaller thickness is more difficult, thereby increasing the difficulty of manufacturing process.

In some embodiments, the difference between the maximum thicknesses of the first capping unit 141 and the third capping unit 143 is less than the difference between the maximum thicknesses of the third capping unit 143 and the second capping unit 142. With this arrangement, the thickness difference between the first capping unit 141 and the third capping unit 143 is relatively smaller, and the thickness difference between the third capping unit 143 and the second capping unit 142 is relatively larger, so as to better improve the light extraction efficiency of blue light. Optionally, the difference between the maximum thicknesses of the first capping unit 141 and the third capping unit 143 is greater than or equal to 30 angstroms and less than or equal to 60 angstroms; the difference between the maximum thicknesses of the third capping unit 143 and the second capping unit 142 is greater than or equal to 60 angstroms and less than or equal to 100 angstroms.

In some embodiments, the first capping unit 141, the second capping unit 142, and the third capping unit 143 include same materials. With this arrangement, three capping units described above can be formed using the same materials and substantially the same process conditions. By controlling the manufacturing times of the three capping units to be different, the first capping unit 141, the second capping unit 142 and the third capping unit 143 with different thicknesses can be manufactured respectively. Therefore, the manufacturing process of the capping layer 14 is simplified.

In some embodiments, as shown in FIG. 1, the display panel 100 further includes a filter layer 18. The filter layer 18 is located on the side of the thin film encapsulation layer 15 away from the light emitting device layer 13. The filter layer 18 includes a first color resist unit 182, a second color resist unit 183 and a third color resist unit 184 with different colors, and a black matrix 181.

The black matrix 181 includes a plurality of openings 181a, the first color resist unit 182, the second color resist unit 183, and the third color resist unit 184 are respectively disposed in the plurality of openings 181a. The orthographic projections of the plurality of openings 181a on the substrate layer 11 respectively overlap the orthographic projections of the first light emitting layer 1321, the second light emitting layer 1322 and the third light emitting layer 1323 on the substrate layer 11.

The orthographic projection of the first color resist unit 182 on the substrate layer 11 overlaps the orthographic projections of the first light emitting layer 1321 and the first capping unit 141 on the substrate layer 11. The color of the first color resist unit 182 is same as the color of the light with the first wavelength λ₁. In a case where the light with the first wavelength λ₁ is red light, the first color resist unit 182 is a red color resistor.

The orthographic projection of the second color resist unit 183 on the substrate layer 11 overlaps the orthographic projections of the second light emitting layer 1322 and the second capping unit 142 on the substrate layer 11. The color of the second color resist unit 183 is the same as the color of the light with the second wavelength λ₂. In a case where the light with the second wavelength λ₂ is blue light, the second color resist unit 183 is a blue color resistor.

The orthographic projection of the third color resist unit 184 on the substrate layer 11 overlaps the orthographic projections of the third light emitting layer 1323 and the third capping unit 143 on the substrate layer 11. The color of the third color resist unit 184 is same as the color of the light with the third wavelength λ₃. In a case where the light with the third wavelength λ₃ is green light, the third color resist unit 184 is a green color resistor.

In some embodiments, the first wavelength λ₁ includes a first maximum transmittance wavelength λₐ. The transmittance of light with the first maximum transmittance wavelength λₐ passing through the first color resist unit 182 is the maximum transmittance of light with the first wavelength λ₁ passing through the first color resist unit 182. The thickness d1 of the first capping unit 141 meets the formula d1=0.5λₐm₁-A1-B1-C. A1 is the thickness of the first transparent anode 1317 described above. B1 is the sum of the thicknesses of film layers located between the first transparent anode 1317 and the cathode layer 133. C is the thickness of the cathode layer 133 described above, mi is an integer greater than or equal to 1. In this way, the thickness d1 of the first capping unit 141 is related to the first maximum transmittance wavelength λₐ. The design of the thickness d1 of the first capping unit 141 can increase the transmittance of light with the first maximum transmittance wavelength λₐ passing through the first microcavity structure 201. In combination with the fact that the transmittance of light with the first maximum transmittance wavelength λₐ passing through the first color resist unit 182 is the maximum transmittance of light with the first wavelength λ₁ passing through the first color resist unit 182, the light extraction efficiency of light with the first maximum transmittance wavelength λₐ emitted by the display panel 100 is significantly increased. The increase of the light extraction efficiency of light with the maximum transmittance wavelength λₐ can reduce the power consumption when displaying a bright picture, thereby reducing the power consumption of the display device when displaying a bright picture, and reducing heat to address the heating problem.

In some embodiments, the second wavelength λ₂ includes a second maximum transmittance wavelength λ_{b}, and the transmittance of light with the second maximum transmittance wavelength λ_{b} passing through the second color resist unit 183 is the maximum transmittance of light with the second wavelength λ₂ passing through the second color resist unit 183. The thickness d2 of the second capping unit 142 meets the formula d2=0.5λ_{b}m₂-A2-B2-C, A2 is the thickness of the second transparent anode 1318 described above. B2 is the sum of the thicknesses of film layers located between the second transparent anode 1318 and the cathode layer 133. m₂ is an integer greater than or equal to 1. C is the thickness of the cathode layer 133 described above. In this way, the thickness d2 of the second capping unit 142 is related to the second maximum transmittance wavelength λ_{b}. The design of the thickness d2 of the second capping unit 142 can increase the transmittance of light with the second maximum transmittance wavelength λ_{b} passing through the second microcavity structure 202. In combination with the fact that the transmittance of light with the second maximum transmittance wavelength λ_{b} passing through the second color resist unit 183 is the maximum transmittance of light with the second wavelength λ₂ passing through the second color resist unit 183, the light extraction efficiency of light with the second maximum transmittance wavelength λ_{b} emitted by the display panel 100 is significantly increased. The increase of the light extraction efficiency of light with the second maximum transmittance wavelength λ_{b} can reduce the power consumption when displaying a bright picture, thereby reducing the power consumption of the display device when displaying a bright picture, and reducing heat to address the heating problem.

In some embodiments, the third wavelength λ₃ includes a third maximum transmittance wavelength λ_{c}. The transmittance of light with the third maximum transmittance wavelength λ_{c} passing through the third color resist unit 184 is the maximum transmittance of light with the third wavelength λ₃ passing through the third color resist unit 184. The thickness d3 of the third capping unit 143 meets the formula d3=0.5λ_{c}m₃-A3-B3-C, A3 is the thickness of the third transparent anode 1319. B3 is the sum of the thicknesses of the film layers located between the third transparent anode 1319 and the cathode layer 133. m₃ is an integer greater than or equal to 1. In this way, the thickness d3 of the third capping unit 143 is related to the third maximum transmittance wavelength λ_{c}. The design of the thickness d3 of the third capping unit 143 can increase the transmittance of light with the third maximum transmittance wavelength λ_{c} passing through the third microcavity structure 203. In combination with the fact that the transmittance of light with the third maximum transmittance wavelength λ_{c} passing through the third color resist unit 184 is the maximum transmittance of light with the third wavelength λ₃ passing through the third color resist unit 184, the light extraction efficiency of light with the third maximum transmittance wavelength λ_{c} emitted by the display panel 100 is significantly increased. The increase of the light extraction efficiency of light with the maximum transmittance wavelength λ_{c} can reduce the power consumption when displaying a bright picture, thereby reducing the power consumption of the display device when displaying a bright picture, and reducing heat to address the heating problem.

It can be seen that in the present disclosure, according to the first maximum transmittance wavelength λₐ corresponding to the maximum transmittance of light passing through the first color resist unit 182, the second maximum transmittance wavelength λ_{b} corresponding to the maximum transmittance of light passing through the second color resist unit 183, and the third maximum transmittance wavelength λ_{c} corresponding to the maximum transmittance of light passing through the third color resist unit 184, the thicknesses of the first capping unit 141, the second capping unit 142 and the third capping unit are respectively determined, so as to further improve the transmittance of light with the first maximum transmittance wavelength λₐ, the second maximum transmittance wavelength λ_{b}, and the third maximum transmittance wavelength λ_{c}.

In some embodiments, m₁, m₂, and m₃ may be the same. For example, each of m₁, m₂, and m₃ is equal to 2. In other embodiments, one of m₁, m₂, and m₃ may be different from the other two ones. In other embodiments, m₁, m₂ and m₃ may also be different from each other.

In some embodiments, each of m₁, m₂, and m₃ is less than or equal to 3. Optionally, each of m₁, m₂ and m₃ is less than or equal to 2. In this way, the microcavity length of the first microcavity structure 201 can better match the thicknesses of the film layers constituting the first microcavity structure 201, the microcavity length L2 of the second microcavity structure 202 can better match the thicknesses of the film layers constituting the second microcavity structure 202, and the microcavity length L3 of the third microcavity structure 203 can better match the thicknesses of the film layers constituting the third microcavity structure 203. In this way, while increasing the light extraction efficiencies of light with the first wavelength λ₁, light with the second wavelength λ₂, and light with the third wavelength λ₃, the difficulty of manufacturing various film layers forming the first microcavity structure 201, various film layers forming the second microcavity structure 202, and various film layers forming the third microcavity structure 203 is reduced. The functions of various film layers of the first microcavity structure 201, various film layers of the second microcavity structure 202, and various films of the third microcavity structure 203 are guaranteed, thereby further ensuring the overall display effect of the display panel.

In some embodiments, at least one of the maximum transmittance of the light with the first wavelength λ₁ passing through the first color resist unit 182 and the maximum transmittance of the light with the third wavelength λ₃ passing through the third color resist unit 184 is less than the maximum transmittance of light with the second wavelength λ₂ passing through the second color resist unit 183. With this arrangement, through the differential design of the thicknesses of the capping layer described above and combining with the design of the filter layer 18, the maximum transmittance of the light with the second wavelength λ₂ is significantly increased, that is, the maximum transmittance of blue light is increased, so that the current required to emit blue light is reduced, thereby reducing the power consumption of the display panel required during display.

It should be noted that during display, the light emitting efficiencies of the green light emitting layer and the red light emitting layer are relatively higher, and the current required to emit green light and red light is relatively smaller; the light emitting efficiency of the blue light emitting layer is lower, and the current required to emit the blue light is larger. Therefore, the present disclosure adopts the differential design of the capping layer described above and combines with the design of the filter layer 18 to increase the light extraction efficiency of blue light, which is beneficial to reducing the current required when emitting blue light, thereby reducing the power consumption of the display panel required during display.

In some embodiments, the first maximum transmittance wavelength λₐ is greater than or equal to 620 nanometers and less than or equal to 640 nanometers, and the transmittance of light with the first maximum transmittance wavelength λₐ passing through the first color resist unit 182 is greater than or equal to 45%. In this way, the light extraction efficiency of light with the first maximum transmittance wavelength λₐ is guaranteed, that is, the maximum light extraction efficiency of red light emitted by the display panel 100 is guaranteed.

Optionally, the first maximum transmittance wavelength λₐ is greater than or equal to 625 nanometers and less than or equal to 635 nanometers.

Optionally, the transmittance of light with the first maximum transmittance wavelength λₐ passing through the first color resist unit 182 is greater than or equal to 50% and less than or equal to 85%. Optionally, the transmittance of light with the first maximum transmittance wavelength λₐ passing through the first color resist unit 182 is greater than or equal to 60% and less than or equal to 75%. In this way, the light extraction efficiency of light with the first maximum transmittance wavelength λₐ is further increased, and the current required for emitting red light is reduced, thereby reducing the power consumption required for emitting blue light, and thus balancing the brightness and power consumption of red light.

In some embodiments, the second maximum transmittance wavelength λ_{b} is greater than or equal to 420 nanometers and less than or equal to 450 nanometers, and the transmittance of the light with the second maximum transmittance wavelength λ_{b} passing through the second color resist unit 183 is greater than or equal to 45%. In this way, the light extraction efficiency of light with the second maximum transmittance wavelength λ_{b} is guaranteed, that is, the maximum light extraction efficiency of blue light emitted by the display panel 100 is guaranteed.

Optionally, the second maximum transmittance wavelength λ_{b} is greater than or equal to 425 nanometers and less than or equal to 440 nanometers. Optionally, the second maximum transmittance wavelength λ_{b} is greater than or equal to 428 nanometers and less than or equal to 435 nanometers.

Optionally, the transmittance of the light with the second maximum transmittance wavelength λ_{b} passing through the second color resist unit is greater than or equal to 60% and less than or equal to 95%. Optionally, the transmittance of the light with the second maximum transmittance wavelength λ_{b} passing through the second color resist unit is greater than or equal to 65% and less than or equal to 90%. In this way, while further improving the light extraction efficiency of the light with the second maximum transmittance wavelength λ_{b}, the current required to emit blue light is reduced, thereby reducing the power consumption required to emit blue light, and thus balancing the brightness and power consumption of blue light.

In some embodiments, the third maximum transmittance wavelength λ_{c} is greater than or equal to 495 nanometers and less than or equal to 530 nanometers, and the transmittance of light with the third maximum transmittance wavelength λ_{c} passing through the third color resist unit 184 is greater than or equal to 45%. In this way, the light extraction efficiency of the light with the third maximum transmittance wavelength λ_{c} is guaranteed, that is, the maximum light extraction efficiency of the green light emitted by the display panel 100 is guaranteed.

Optionally, the third maximum transmittance wavelength λ_{c} is greater than or equal to 495 nanometers and less than or equal to 530 nanometers.

Optionally, the transmittance of light with the third maximum transmittance wavelength λ_{c} passing through the third color resist unit is greater than or equal to 50% and less than or equal to 85%. Optionally, the transmittance of the light with the third maximum transmittance wavelength λ_{c} passing through the third color resist unit is greater than or equal to 60% and less than or equal to 75%. In this way, while further improving the light extraction efficiency of the light with the third maximum transmittance wavelength λ_{c}, the current required to emit green light is reduced, thereby reducing the power consumption required to emit the green light, and thus balancing the brightness and power consumption of green light.

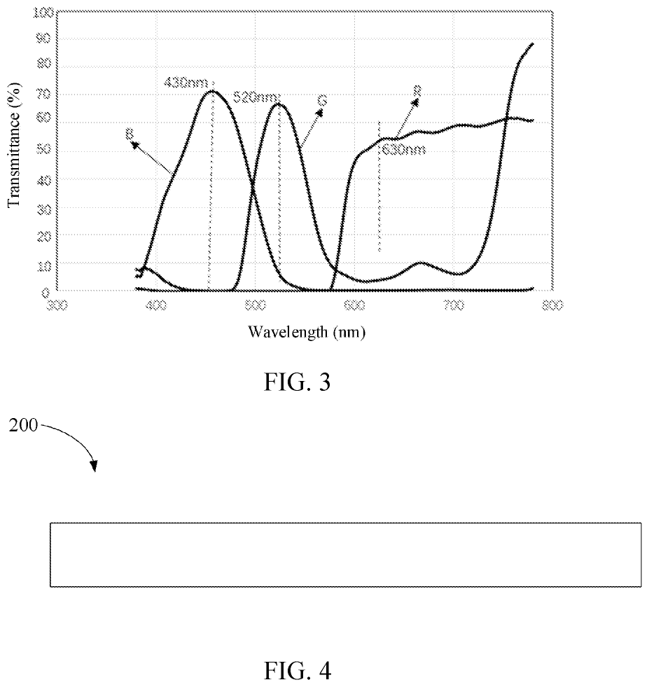

Referring to FIG. 3, which shows the spectrum test result of the transmittance of the first color resist unit, the second color resist unit and the third color resist unit of the filter layer in the display panel for light with different wavelengths in some embodiments provided by the present disclosure. In FIG. 3, B represents the transmittance of the second color resist unit (i.e., the blue color resistor) for light with different wavelengths, R represents the transmittance of the first color resist unit (i.e., the red color resistor) for light with different wavelengths, and G represents the transmittance of the third color resist unit (i.e., the green color resistor) for light with different wavelengths.

It can be seen from FIG. 3 that in the present disclosure, the second color resist unit 183 has a maximum transmittance for blue light with a wavelength of 430 nanometers, and the maximum transmittance is greater than 70%; the third color resist unit 184 has a maximum transmittance for green light with a wavelength of 520 nanometers, and the maximum transmittance is greater than 65% and less than or equal to 70%; the first color resist unit 182 has a maximum transmittance for red light with a wavelength of 630 nanometers, and the maximum transmittance is greater than 50% and less than or equal to 60%. Therefore, the filter layer 18 of the present disclosure has high transmittance for the light emitted by the light emitting layer 132.

In the present disclosure, the design of the filter layer 18 having high transmittance and in combination with the fact that the differential design of the thicknesses of the capping layer 14 is related to the maximum transmittance of the filter layer 18 for light with different wavelengths can significantly improve the display brightness of the display panel 100.

Specifically, in the present disclosure, the filter layer 18 having high transmittance is matched with a differential design of the thicknesses of the capping layer 14. It is verified through examinations that, in a case where the driving current corresponding to red light is 98 nA, the driving current corresponding to blue light is 118 nA, and the driving current corresponding to green light is 97 nA, the brightness of red light emitted by the display panel 100 can reach up to 197.02 nit, the brightness of green light can reach up to 540.46 nit, the brightness of blue light can reach up to 60.38 nit, and the brightness of white light can reach up to 864.9 nit.

While in related technologies, the capping layer is designed as a whole layer, that is, in a case where the capping layer has a uniform thickness, when the driving current corresponding to red light is 98 nA, the driving current corresponding to blue light is 118 nA, and the driving current corresponding to green light is 97 nA, the brightness of red light is 151 nit, the brightness of blue light is 30 nit, the brightness of green light is 415 nit, and the brightness of white light is 508 nit.

It can be seen from the above that compared with related technologies, the filter layer 18 having high transmittance in combination with the differential design of the thicknesses of the capping layer 14 in the present disclosure can not only increase the brightness of red light, blue light and green light, but also increase the brightness of white light by 70%. Moreover, the brightness of blue light can be increased by nearly 100%.

In some embodiments of the present disclosure, the filter layer 18 is used to replace the polarizer in the related art, that is, polarizer-less technology (i.e., Pol-less technology) is used, so that while the contrast of the display panel 100 during display is guaranteed, the filter layer 18 has a higher transmittance for the light emitted by the light emitting device layer 13, thereby improving the light extraction efficiency of the display panel 100. Moreover, based on the fact that different color resistors of the filter layer 18 each has the maximum transmittance for light with different specific wavelengths, the thicknesses of the first capping unit, the second capping unit and the third capping unit are respectively determined according to different specific wavelengths corresponding to the maximum transmittance. Therefore, while realizing the differential design of the capping layer 14, the light extraction efficiency of the display panel 100 can be significantly improved, thereby improving the display brightness of the display panel 100.

In some embodiments, the display panel 100 further includes a protective layer 16. The protective layer 16 is disposed between the capping layer 14 and the thin film encapsulation layer 15. In the process of forming the thin film encapsulation layer 15, the protective layer 16 plays a protective role on the capping layer 14. The material of the protective layer 16 includes, but is not limited to, inorganic materials such as lithium fluoride.

In some embodiments, the display panel 100 further includes a touch layer 17, the touch layer is disposed between the thin film encapsulation layer 15 and the filter layer 18. The touch layer 17 may be a mutual capacitive touch layer or a self-capacitive touch layer. The touch layer 17 includes one or more touch electrodes. The orthographic projections of the touch electrodes on the substrate layer 11 overlap the orthographic projection of the black matrix 181 on the substrate layer 11, so as to reduce the reflectivity of the touch electrodes to the light and improve the display effect of the display panel 100.

In some embodiments, the display panel 100 further includes a planarization layer 19, the planarization layer 19 covers the surface of the filter layer 18 away from the substrate layer 11. The planarization layer 19 plays a role of planarization. The planarization layer 19 is light transmissive. The planarization layer 19 includes organic materials.

The display panel 100 further includes a driving circuit layer 121, the driving circuit layer 121 is disposed between the light emitting device layer 13 and the substrate layer 11. The anode layer 131 is disposed on the driving circuit layer 121. The driving circuit layer 121 includes a plurality of driving circuits, and the plurality of driving circuits are respectively connected to the first anode 1311, the second anode 1312 and the third anode 1313.

As shown in FIG. 1, the display panel 100 further includes a pixel definition layer 122 located on the anode layer 131 and the driving circuit layer 121. The pixel definition layer 122 includes a plurality of pixel openings 122a. The plurality of pixel openings 122a expose a part of the first anode 1311, a part of the second anode 1312, and a part of the third anode 1313. The first light emitting layer 1321, the second light emitting layer 1322 and the third light emitting layer 1323 are respectively disposed in the plurality of pixel openings 122a.

In summary, for the display panel of the present disclosure, the refractive index of the capping layer is greater than the refractive index of the cathode layer, which is beneficial to improving the light extraction efficiency of the light emitted by the light emitting layer incident from the cathode layer to the capping layer. Furthermore, the first light emitting layer emits light with the first wavelength λ₁, the second light emitting layer emits light with the second wavelength λ₂, and the first wavelength λ₁ is greater than the second wavelength λ₂. The orthographic projection of the first capping unit on the substrate layer overlaps the orthographic projection of the first light emitting layer on the substrate layer. The orthographic projection of the second capping unit on the substrate layer overlaps the orthographic projection of the second light emitting layer on the substrate layer. The thickness of at least a part of the first capping unit is greater than the thickness of at least a part of the second capping unit. With this arrangement, the first capping unit having a larger thickness is provided for the first wavelength λ₁ which is a larger wavelength. The second capping unit having a smaller thickness is provided for the second wavelength λ₂ which is a smaller wavelength. The thicknesses of the capping layer are designed differentially for light with different wavelengths. The microcavity length of the microcavity structure including the first capping unit matches the first wavelength λᵢ, and the microcavity length of the microcavity structure including the second capping unit matches the second wavelength λ₂, which are beneficial to further increasing the light extraction efficiencies of the light with the first wavelength and the light with the second wavelength simultaneously. The current of the display panel when displaying a bright picture is reduced, thereby reducing the power consumption of the display device when displaying a bright picture, and reducing heat to address the heating problem.

Based on the same inventive concept, referring to FIG. 4, the present disclosure further provides a display device 200. The display device 200 includes the display panel 100 described in any of the above embodiments. The display device 200 can be applied to electronic devices such as mobile phones, tablet computers, and personal computers.

The description of the above embodiments is only intended to help understand the technical solution and its core idea of the present disclosure. Those skilled in the art should understand that: it is still possible to modify the technical solutions recorded in the above embodiments, or to equivalently replace part of the technical features thereof. However, these modifications or replacements do not cause the essence of the corresponding technical solutions to depart from the scope of the technical solutions of the embodiments of the present disclosure.

What is claimed is:

1. A display panel comprising:
a substrate layer;
a light emitting device layer disposed on the substrate layer and comprising a transparent anode layer, a light emitting layer and a cathode layer, wherein the light emitting layer is disposed between the transparent anode layer and the cathode layer, the transparent anode layer is located on a side of the light emitting layer close to the substrate layer, the transparent anode layer comprises a first transparent anode and a second transparent anode spaced apart, the light emitting layer comprises a first light emitting layer disposed on the first transparent anode and a second light emitting layer disposed on the second transparent anode, the first light emitting layer emits light with a first wavelength λ₁, the second light emitting layer emits light with a second wavelength λ₂, and the first wavelength λ₁ is greater than the second wavelength λ₂;
a thin film encapsulation layer located on a side of the light emitting device layer away from the substrate layer; and
a capping layer disposed between the cathode layer and the thin film encapsulation layer, wherein a refractive index of the capping layer is greater than a refractive index of the cathode layer, and the capping layer comprises a first capping unit and a second capping unit, an orthographic projection of the first capping unit on the substrate layer overlaps an orthographic projection of the first light emitting layer on the substrate layer, an orthographic projection of the second capping unit on the substrate layer overlaps an orthographic projection of the second light emitting layer on the substrate layer, and a thickness of at least a part of the first capping unit is greater than a thickness of at least a part of the second capping unit.

2. The display panel according to claim 1, wherein the transparent anode layer further comprises a third transparent anode spaced apart from the first transparent anode and the second transparent anode, the light emitting layer further comprises a third light emitting layer disposed on the third transparent anode, the third light emitting layer emits light with a third wavelength λ₃, and the third wavelength λ₃ is greater than the second wavelength λ₂;
the capping layer further comprises a third capping unit, an orthographic projection of the third capping unit on the substrate layer overlaps an orthographic projection of the third light emitting layer on the substrate layer, and a thickness of at least a part of the third capping unit is greater than the thickness of at least a part of the second capping unit;
when the first wavelength λ₁ is greater than the third wavelength λ₃, the thickness of at least a part of the first capping unit is greater than the thickness of at least a part of the third capping unit; or, when the first wavelength λ₁ is less than the third wavelength λ₃, the thickness of at least a part of the first capping unit is less than the thickness of at least a part of the third capping unit.

3. The display panel according to claim 2, wherein the display panel further comprises:
a filter layer, wherein the filter layer is located on a side of the thin film encapsulation layer away from the light emitting device layer and comprises a first color resist unit, a third color resist unit and a second color resist unit with different colors from each other, an orthographic projection of the first color resist unit on the substrate layer overlaps orthographic projections of the first light emitting layer and the first capping unit on the substrate layer, an orthographic projection of the second color resist unit on the substrate layer overlaps orthographic projections of the second light emitting layer and the second capping unit on the substrate layer, and an orthographic projection of the third color resist unit on the substrate layer overlaps orthographic projections of the third light emitting layer and the third capping unit on the substrate layer;
the first wavelength λ₁ comprises a first maximum transmittance wavelength λₐ, a transmittance of light with the first maximum transmittance wavelength λₐ passing through the first color resist unit is a maximum transmittance of light with the first wavelength λ₁ passing through the first color resist unit, a thickness d1 of the first capping unit meets a formula d1=0.5λₐm₁-A1-B1-C, A1 is a thickness of the first transparent anode, B1 is a sum of thicknesses of film layers located between the first transparent anode and the cathode layer, C is a thickness of the cathode layer, and m₁ is an integer greater than or equal to 1;
the second wavelength λ₂ comprises a second maximum transmittance wavelength λ_{b}, a transmittance of light with the second maximum transmittance wavelength λ_{b} passing through the second color resist unit is a maximum transmittance of light with the second wavelength λ₂ passing through the second color resist unit, a thickness d2 of the second capping unit meets a formula d2=0.5λ_{b}m₂-A2-B2-C, A2 is a thickness of the second transparent anode, B2 is a sum of thicknesses of film layers located between the second transparent anode and the cathode layer, and m₂ is an integer greater than or equal to 1;
the third wavelength λ₃ comprises a third maximum transmittance wavelength λ_{c}, a transmittance of light with the third maximum transmittance wavelength λ_{c} passing through the third color resist unit is a maximum transmittance of light with the third wavelength λ₃ passing through the third color resist unit, a thickness d3 of the third capping unit meets a formula d3=0.5λ_{c}m₃-A3-B3-C, A3 is a thickness of the third transparent anode, B3 is a sum of thicknesses of film layers located between the third transparent anode and the cathode layer, and m₃ is an integer greater than or equal to 1.

4. The display panel according to claim 3, wherein the light with the first wavelength λ₁ is red light, and the first color resist unit is a red color resistor;
the light with the second wavelength λ₂ is blue light, and the second color resist unit is a blue color resistor; and
the light with the third wavelength λ₃ is green light, and the third color resist unit is a green color resistor.

5. The display panel according to claim 4, wherein at least one of the maximum transmittance of the light with the first wavelength λ₁ passing through the first color resist unit and the maximum transmittance of the light with the third wavelength λ₃ passing through the third color resist unit is less than the maximum transmittance of the light with the second wavelength λ₂ passing through the second color resist unit.

6. The display panel according to claim 4, wherein the first maximum transmittance wavelength λₐ is greater than or equal to 620 nanometers and less than or equal to 640 nanometers, and the transmittance of the light with the first maximum transmittance wavelength passing through the first color resist unit is greater than or equal to 45%;
the second maximum transmittance wavelength λ_{b} is greater than or equal to 420 nanometers and less than or equal to 450 nanometers, and the transmittance of the light with the second maximum transmittance wavelength λ_{b} passing through the second color resist unit is greater than or equal to 45%; and
the third maximum transmittance wavelength λ_{c} is greater than or equal to 495 nanometers and less than or equal to 530 nanometers, and the transmittance of the light with the third maximum transmittance wavelength λ_{c} passing through the third color resist unit is greater than or equal to 45%.

7. The display panel according to claim 6, wherein the transmittance of the light with the first maximum transmittance wavelength λₐ passing through the first color resist unit is greater than or equal to 50% and less than or equal to 85%;
the transmittance of the light with the second maximum transmittance wavelength λ_{b} passing through the second color resist unit is greater than or equal to 60% and less than or equal to 95%; and
the transmittance of the light with the third maximum transmittance wavelength λ_{c} passing through the third color resist unit is greater than or equal to 50% and less than or equal to 85%.

8. The display panel according to claim 4, wherein the thickness of the first capping unit is greater than or equal to 600 angstroms and less than or equal to 700 angstroms, the thickness of the second capping unit is greater than or equal to 450 angstroms and less than or equal to 530 angstroms, and the thickness of the third capping unit is greater than or equal to 540 and less than or equal to 600 angstroms.

9. The display panel according to claim 3, wherein each of m₁, m₂ and m₃ is less than or equal to 3.

10. The display panel according to claim 3, wherein a difference between maximum thicknesses of any two ones of the first capping unit, the second capping unit and the third capping unit is greater than or equal to 20 angstroms and less than or equal to 300 angstroms.

11. The display panel according to claim 3, wherein the display panel further comprises:
a protective layer disposed between the capping layer and the thin film encapsulation layer; and
a touch layer disposed between the thin film encapsulation layer and the filter layer.

12. The display panel according to claim 2, wherein at least two ones of the first capping unit, the second capping unit and the third capping unit are disposed adjacently and spaced apart.

13. The display panel according to claim 2, wherein at least two ones of the first capping unit, the second capping unit and the third capping unit are disposed adjacently and in contact with each other.

14. The display panel according to claim 2, wherein the orthographic projection of the first light emitting layer on the substrate layer is within the orthographic projection of the first capping unit on the substrate layer, the orthographic projection of the second light emitting layer on the substrate layer is within the orthographic projection of the second capping unit on the substrate layer, and the orthographic projection of the third light emitting layer on the substrate layer is within the orthographic projection of the third capping unit on the substrate layer.

15. The display panel according to claim 2, wherein the first capping unit, the second capping unit and the third capping unit comprise a same material.

16. The display panel according to claim 1, wherein the refractive index of the capping layer is greater than or equal to 1.6 and less than or equal to 1.9, and the refractive index of the cathode layer is greater than or equal to 1.4 and less than or equal to 1.6.

17. A display device comprising a display panel, wherein the display panel comprises:
a substrate layer;
a light emitting device layer disposed on the substrate layer and comprising a transparent anode layer, a light emitting layer and a cathode layer, wherein the light emitting layer is disposed between the transparent anode layer and the cathode layer, the transparent anode layer is located on a side of the light emitting layer close to the substrate layer, the transparent anode layer comprises a first transparent anode and a second transparent anode spaced apart, the light emitting layer comprises a first light emitting layer disposed on the first transparent anode and a second light emitting layer disposed on the second transparent anode, the first light emitting layer emits light with a first wavelength λ₁, the second light emitting layer emits light with a second wavelength λ₂, and the first wavelength λ₁ is greater than the second wavelength λ₂;
a thin film encapsulation layer located on a side of the light emitting device layer away from the substrate layer; and
a capping layer disposed between the cathode layer and the thin film encapsulation layer, wherein a refractive index of the capping layer is greater than a refractive index of the cathode layer, and the capping layer comprises a first capping unit and a second capping unit, an orthographic projection of the first capping unit on the substrate layer overlaps an orthographic projection of the first light emitting layer on the substrate layer, an orthographic projection of the second capping unit on the substrate layer overlaps an orthographic projection of the second light emitting layer on the substrate layer, and a thickness of at least a part of the first capping unit is greater than a thickness of at least a part of the second capping unit.

18. The display device according to claim 17, wherein the transparent anode layer further comprises a third transparent anode spaced apart from the first transparent anode and the second transparent anode, the light emitting layer further comprises a third light emitting layer disposed on the third transparent anode, the third light emitting layer emits light with a third wavelength λ₃, and the third wavelength λ₃ is greater than the second wavelength λ₂;
the capping layer further comprises a third capping unit, an orthographic projection of the third capping unit on the substrate layer overlaps an orthographic projection of the third light emitting layer on the substrate layer, and a thickness of at least a part of the third capping unit is greater than the thickness of at least a part of the second capping unit;
when the first wavelength λ₁ is greater than the third wavelength λ₃, the thickness of at least a part of the first capping unit is greater than the thickness of at least a part of the third capping unit; or, when the first wavelength λ₁ is less than the third wavelength λ₃, the thickness of at least a part of the first capping unit is less than the thickness of at least a part of the third capping unit.

19. The display device according to claim 18, wherein the display panel further comprises:
a filter layer, wherein the filter layer is located on a side of the thin film encapsulation layer away from the light emitting device layer and comprises a first color resist unit, a third color resist unit and a second color resist unit with different colors from each other, an orthographic projection of the first color resist unit on the substrate layer overlaps orthographic projections of the first light emitting layer and the first capping unit on the substrate layer, an orthographic projection of the second color resist unit on the substrate layer overlaps orthographic projections of the second light emitting layer and the second capping unit on the substrate layer, and an orthographic projection of the third color resist unit on the substrate layer overlaps orthographic projections of the third light emitting layer and the third capping unit on the substrate layer;
the first wavelength λ₁ comprises a first maximum transmittance wavelength λₐ, a transmittance of light with the first maximum transmittance wavelength λₐ passing through the first color resist unit is a maximum transmittance of light with the first wavelength λ₁ passing through the first color resist unit, a thickness d1 of the first capping unit meets a formula d1=0.5λₐm₁-A1-B1-C, A1 is a thickness of the first transparent anode, B1 is a sum of thicknesses of film layers located between the first transparent anode and the cathode layer, C is a thickness of the cathode layer, and m₁ is an integer greater than or equal to 1;
the second wavelength λ₂ comprises a second maximum transmittance wavelength λ_{b}, a transmittance of light with the second maximum transmittance wavelength λ_{b} passing through the second color resist unit is a maximum transmittance of light with the second wavelength λ₂ passing through the second color resist unit, a thickness d2 of the second capping unit meets a formula d2=0.5λ_{b}m₂-A2-B2-C, A2 is a thickness of the second transparent anode, B2 is a sum of thicknesses of film layers located between the second transparent anode and the cathode layer, and m₂ is an integer greater than or equal to 1;
the third wavelength λ₃ comprises a third maximum transmittance wavelength λ_{c}, a transmittance of light with the third maximum transmittance wavelength λ_{c} passing through the third color resist unit is a maximum transmittance of light with the third wavelength λ₃ passing through the third color resist unit, a thickness d3 of the third capping unit meets a formula d3=0.5λ_{c}m₃-A3-B3-C, A3 is a thickness of the third transparent anode, B3 is a sum of thicknesses of film layers located between the third transparent anode and the cathode layer, and m₃ is an integer greater than or equal to 1.

20. The display device according to claim 19, wherein the light with the first wavelength λ₁ is red light, and the first color resist unit is a red color resistor;
the light with the second wavelength λ₂ is blue light, and the second color resist unit is a blue color resistor; and
the light with the third wavelength λ₃ is green light, and the third color resist unit is a green color resistor.
